(19) United States
(12) Patent Application Publication
(10) Pub. No.: US 2024/0186230 A1
(43) Pub. Date: Jun. 6, 2024

(54) COMPONENT PACKAGE SUBSTRATE STRUCTURE AND MANUFACTURING METHOD THEREOF

(71) Applicant: Zhuhai ACCESS Semiconductor Co., Ltd, Guangdong (CN)

(72) Inventors: Xianming CHEN, Guangdong (CN); Xiaowei XU, Guangdong (CN); Juchen HUANG, Guangdong (CN); Gao HUANG, Guangdong (CN); Benxia HUANG, Guangdong (CN)

(21) Appl. No.: 18/377,399

(22) Filed: Oct. 6, 2023

(30) Foreign Application Priority Data
Dec. 2, 2022 (CN) 2022115428793

(51) Int. Cl. H01L 23/498; H01L 23/00

(52) U.S. Cl. CPC H01L 23/49822; H01L 23/49811; H01L 23/49838; H01L 24/05; H01L 24/19; H01L 24/20; H01L 2224/04026; H01L 2224/19; H01L 2224/2101

(57) ABSTRACT

A method for manufacturing a component package substrate structure includes providing a first temporary bearing plate, fitting components, applying a first dielectric layer to embed the components in the first dielectric layer, applying a second temporary bearing plate, removing the first temporary bearing plate, forming a connection pad for connecting an element terminal on the first dielectric layer, laminating a second dielectric layer on the first dielectric layer, laminating a circuit board on the second dielectric layer, removing the second temporary bearing plate, opening a stepped hole on the second surface, wherein the stepped hole includes a first via hole penetrating the first dielectric layer, an opening of an annular ring structure of the connection pad and a second via hole penetrating the second dielectric layer, and electroplating the stepped hole to form a conductive column, wherein the conductive column renders the connection pad conductive with the circuit layer.

### CROSS-REFERENCE TO RELATED APPLICATION AND CLAIM OF PRIORITY

This application claims the benefit under 35 USC § 119 of Chinese Patent Application No. 2022115428793, filed on Dec. 2, 2022, in the China Intellectual Property Office, the entire disclosure of which is incorporated herein by reference for all purposes.

### BACKGROUND

### 1. Technical Field

The present application relates to the technical field of semiconductor packaging, in particular to a component package substrate structure and a manufacturing method thereof.

### 2. Background Art

With the development of electronic technology, the performance requirements of electronic products are higher and higher, the size requirements are smaller and thinner, so that the high-density integration and miniaturization of electronic components such as chips, package substrates and packaging structures is an inevitable trend.

In the prior art solution, a package substrate embeds a component in a packaging material, and the component is usually mounted in a cavity, and then packaged and built up. However, the process flow for forming the cavity is relatively complicated, especially when a small-sized cavity needs to be formed, and etching the copper pillars by pattern transfer is required, and the process flow is more cumbersome, increasing a lot of process costs and processing time. At the same time, the method for embedding the components first and then building up will lead to the waste of the circuit of the outer substrate, which will cause the loss of components and greatly increase the manufacturing cost.

### SUMMARY

In view of this, an object of the present application is to provide a component package substrate structure and a manufacturing method thereof.

Based on the above-mentioned object, the present application provides a method for manufacturing a component package substrate structure, which includes:
providing a first temporary bearing plate:
fitting a component on the first temporary bearing plate;
applying a first dielectric layer on one side of the fitted component of the first temporary bearing plate, so that the component is embedded in the first dielectric layer; applying a second temporary bearing plate on the first dielectric layer;
removing the first temporary bearing plate to expose a terminal face of the component and a first surface of the first dielectric layer;
forming a connection pad connected to a terminal of the component on the first surface, the connection pad including an annular ring structure;
laminating a second dielectric layer on the first surface, and laminating a circuit board on the second dielectric layer, wherein a surface of the circuit board laminated with the second dielectric layer includes a circuit layer;
removing the second temporary bearing plate to expose a second surface of the first dielectric layer;
opening a stepped hole on the second surface, wherein the stepped hole includes a first via hole penetrating the first dielectric layer, an opening of an annular ring structure of the connection pad and a second via hole penetrating the second dielectric layer, wherein the first via hole, the second via hole and the opening are coaxially provided to expose the circuit layer; and
electroplating the stepped hole to form a conductive column, wherein the conductive column renders the connection pad conductive with the circuit layer.

An embodiment of the present application also provides a component package substrate structure including:
a circuit board having a surface having a circuit layer; a second dielectric layer provided on the circuit layer of the circuit board, the second dielectric layer having a second via hole penetrating the second dielectric layer and exposing the circuit layer;
a component having a terminal face facing the second dielectric layer, a connection pad connected to a terminal of the component being provided on the terminal face, the connection pad including an annular ring structure having an opening, wherein the opening exposes the second via hole;
a first dielectric layer provided on the second dielectric layer and embedding the component, the first dielectric layer having a first via hole penetrating the first dielectric layer and exposing the opening; and
a conductive column filling at least the second via hole and the opening of the connection pad to make the connection pad be conductive with the circuit layer.

The component package substrate structure can be manufactured using the manufacturing method described in the present invention.

It can be seen from the above that the component package substrate structure and the manufacturing method thereof provided in the present application that a component can be embedded after a substrate circuit is completed, the component embedding process can be postponed, the conduction between the postponed component and the substrate circuit is achieved by forming a stepped hole, discard of the component as useless due to the poor substrate circuit can be avoided, the component packaging yield can be improved, the component packaging process cost can be reduced to a certain extent and the processing time can be reduced, the component can be embedded after the circuit quality detection of the outer substrate, and the problem of the discard of the component as useless due to the poor substrate circuit can be solved.

### BRIEF DESCRIPTION OF DRAWINGS

In order to explain the present application or the technical solutions in the related art more clearly, a brief description will be given below with reference to the description of the embodiments or the related art; obviously, the drawings in the description below are merely the embodiments of the present application, and it would have been obvious for a person skilled in the art to obtain other drawings according to these drawings without involving any inventive effort.

FIG. 1 is a schematic cross-sectional view showing one structure of an exemplary component package substrate structure according to an embodiment of the present application:

FIG. 2 is a schematic diagram showing another configuration of an exemplary component package substrate structure according to an embodiment of the present application:

FIGS. 3A-3L show schematic cross-sectional views of intermediate structures of various steps of a method for manufacturing a component package substrate structure according to an embodiment of the present application.

### DETAILED DESCRIPTION

The objects, technical solutions and advantages of the present application will become more apparent from the following detailed description when taken in conjunction with the accompanying drawings.

It should be noted that, unless otherwise defined, technical or scientific terms used in the examples of the present application shall have the ordinary meaning as understood by a person skilled in the art to which the present application belongs. The use of the terms “first”, “second”, and the like in the embodiments herein does not denote any order, quantity, or importance, but rather is used to distinguish one element from another. The word “including” or “includes”, and the like, means that the elements or items preceding the word encompass the elements or items listed after the word and equivalents thereof, but do not exclude other elements or items. “Connected” or “coupled” and like terms are not limited to physical or mechanical connections, but may include electrical connections, whether direct or indirect. “Up”, “down”, “left”, “right”, etc. are only used to indicate a relative positional relationship, which may change accordingly when the absolute position of the object being described changes.

In the technical solution of semiconductor packaging, it is most common to make a blind Cavity, or a through Cavity, and then to mount a component into the Cavity, and then to perform packaging and building up. In this way, the component is usually placed in the innermost layer, and the discard of the outer layer as useless will directly lead to the loss of the embedded device in the inner layer, especially when the integration degree of the embedded chip is higher and higher, the yield loss of the substrate circuit will increase the cost due to the discard of the embedded component as useless. On the other hand, the manufacturing process of Cavity is complicated, which increases the process cost and processing time of the whole packaging process. Therefore, in the prior art solution, there are problems that the process cost and the processing time are very high, and the circuit of the outer substrate is discarded as useless, resulting in the discard of the component as useless, etc.

Based on this, the embodiments of the present application provide a component package substrate structure and a manufacturing method thereof. By embedding a component after an outer substrate circuit is completed, the component embedding process can be postponed, the conduction between the postponed component and the substrate circuit is achieved by forming a stepped hole, discard of the component as useless due to the poor substrate circuit can be avoided, the component packaging yield can be improved, the component packaging process cost can be reduced to a certain extent and the processing time can be reduced, the component can be embedded after the circuit quality detection of the outer substrate, and the problem of the discard of the component as useless due to the poor substrate circuit can be solved.

FIG. 1 shows a schematic diagram of an exemplary component package substrate structure according to an embodiment of the present application.

As shown in the figure, a component package substrate structure provided by an embodiment of the present application may include a circuit board 100, a second dielectric layer 200, a component 300 and a first dielectric layer 400.

The circuit board 100 includes at least one circuit layer. It is understood that a circuit layer is provided at least on one side surface of the circuit board 100 near the component 300. The specific number of circuit layers can be set according to practical application requirements. For example, the circuit layers may include a first circuit layer 110 and a second circuit layer 120 provided on a side of the circuit board 100 remote from the component 300 (i.e. a lower surface of the circuit board 100) and a side of the circuit board 100 close to the component 300 (i.e. an upper surface of the circuit board 100), respectively. In some embodiments, the circuit layer may also include a third circuit layer 130 provided between the first circuit layer 110 and the second circuit layer 120, as shown in FIG. 1. The circuit board 100 may be a multilayer substrate having a plurality of circuit layers. It will be appreciated that corresponding interlayer conductive columns 140 may be provided between two adjacent circuit layers. The number of the interlayer conductive columns 140 may be set as one or more, which is determined according to requirements.

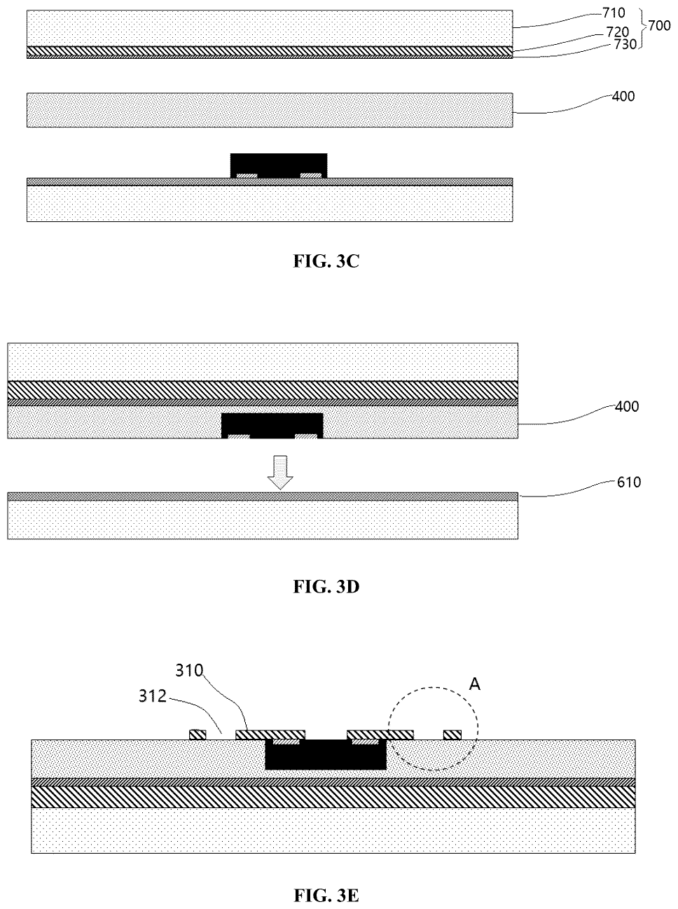

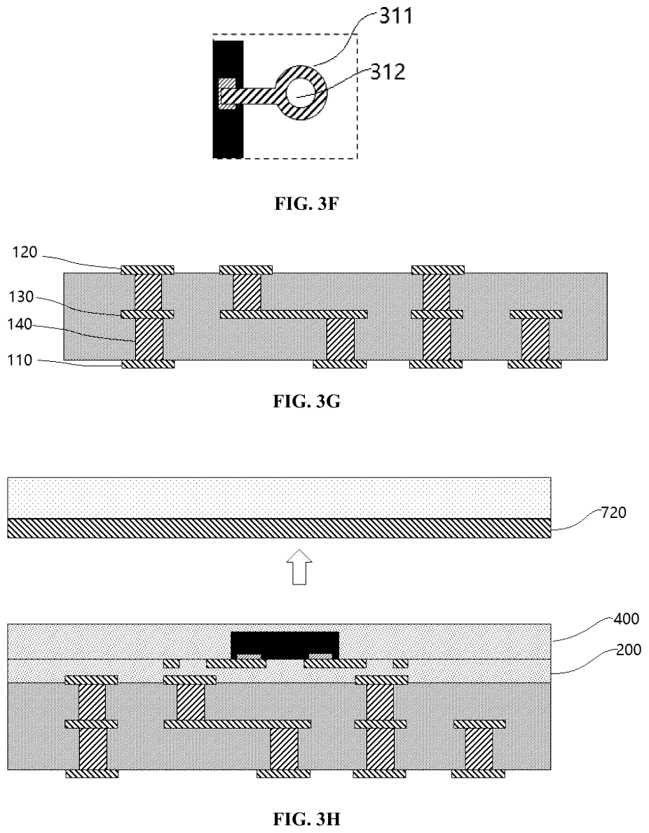

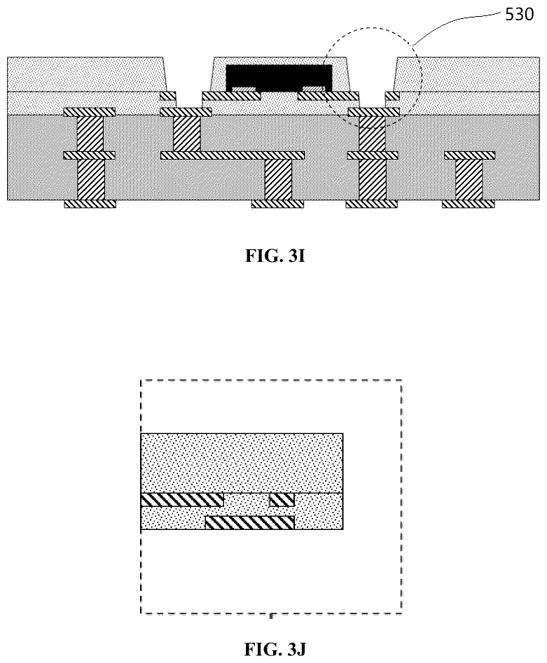

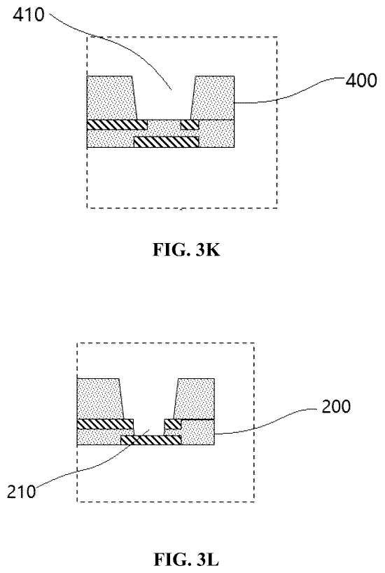

The second dielectric layer 200 may be provided on a side of the circuit board 100 having a circuit layer (e.g. an upper surface of the circuit board 100). As shown in FIG. 3L, the second dielectric layer 200 has a second via hole 210 extending through the second dielectric layer 200 and exposing the second circuit layer 120 on the circuit board 100. The number of the second via holes 210 may correspond to the number of the annular ring structures 311 of the connection pads 310 of the component 300, for example, two. The second via holes 210 may be holes 210 may respectively correspond to the positions of the corresponding inter-layer conductive columns 140 between the line layers of the circuit board 100. An aperture of the second via hole 210 may be the same as the diameter of an opening 312 of the annular ring structure 311.

The component 300 has a terminal face facing the second dielectric layer 200, and a connection pad 310 connected to the terminal of the component 300 is provided on the terminal face, and as shown in FIGS. 3E and 3F, the connection pad 310 includes an annular ring structure 311 having an opening 312 exposing the second via hole 210 (as shown in FIG. 3L) and the second circuit layer 120 of the circuit board 100. The number of the annular ring structures 311 of the connection pads 310 may correspond to the number of the second via holes 210. The opening 312 of the annular ring structure 311 and the second via hole 210 may be provided coaxially.

A first dielectric layer 400 is provided on the second dielectric layer 200, and the first dielectric layer 400 covers the component 300 such that the component 300 is embedded within the first dielectric layer 400. The first dielectric layer 400 has a first via hole 410 (see FIG. 3K) extending through the first dielectric layer 400 and exposing the opening 312 of the annular ring structure 311 of the connection pad 310. The first via hole 410 may be provided coaxially with the opening 312 of the annular ring structure 311 and the second via hole 210. The aperture of the first via hole 410 may be larger than the aperture of the opening 312 of the annular ring structure 311. Thus, the first via hole 410 and the opening 312 and the second via hole 210 form a stepped hole 530 in the vertical direction (as shown in FIG. 3I) to form a communication channel of the component 300 and the circuit board 100. The first dielectric layer 400 may be a packaging layer of the component 300.

The conductive column 500b is formed by filling the stepped hole 530, and the conductive column 500b penetrates at least the second via hole 210 and the opening 312 so that the connection pad 310 can conduct with the circuit layer of the circuit board 100 via the conductive column 500b.

With regard to the component package substrate structure provided in the embodiments of the present application, by providing the connection pad 310 with the annular ring structure 311, in the case where the component 300 is embedded after the circuit board 100 (i.e., the substrate) is completed, the conductive connection pad 310 and the conductive column 500b of the circuit layer can also be formed, so that the embedding process of the component 300 can be postponed, and the cost of the component packaging process and the processing time can be reduced to a certain extent, thus solving the problem of the component being discarded as useless due to the poor circuit of the substrate.

In some embodiments, as shown in FIG. 1, a conductive column may fill a first via hole 410, an opening 312, and a second via hole 210, i.e. through a first dielectric layer 400, an annular ring structure 311, and a second dielectric layer 200. A window pad 510 connecting the conductive column 500b may be formed on the first dielectric layer 400.

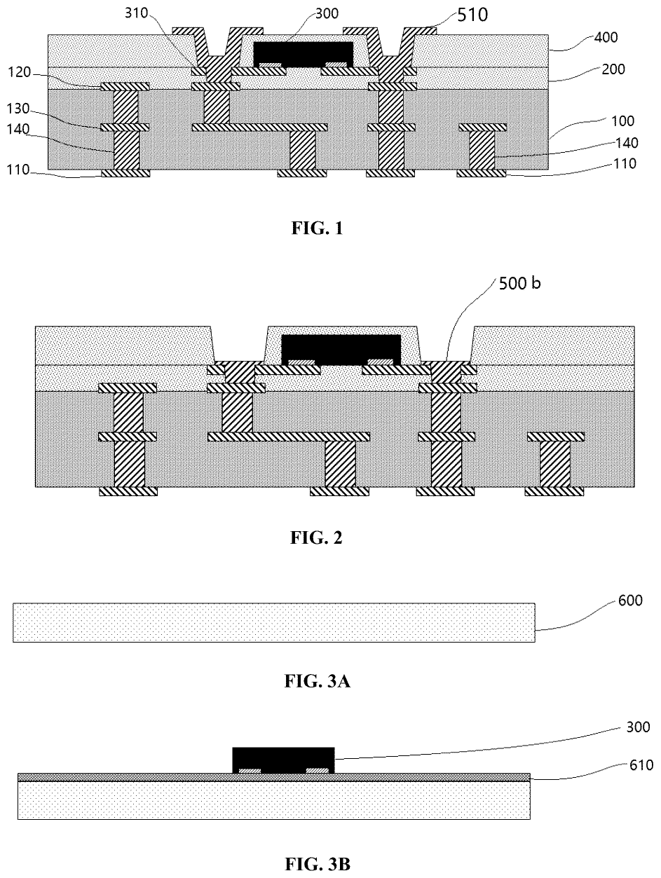

In some embodiments, the conductive column 500b may fill only the opening 312 of the annular ring structure 311 of the second via hole and the connection pad 310, instead of forming the window pad 510 on the first dielectric layer 400, with only the inner line conduction being formed by the conductive column 500b. As shown in FIG. 2, the upper surface of the conductive column 500b may be higher than the upper surface of the second dielectric layer. In other embodiments, the upper surface of the conductive column 500b may be flushed with the upper surface of the second dielectric layer.

In some embodiments, the thickness of the first dielectric layer 400 may be greater than the thickness of the second dielectric layer 200 to better package the device to perform a “plastically-packaging” function.

The first dielectric layer 400 and/or the second dielectric layer 200 may be a resin film or a liquid packaging material or the like, such as RCC, RCF or ABF or the like.

The conductive column 500b/interlayer conductive column 140 mentioned in this embodiment may include at least one copper through-hole post as an IO channel to achieve conduction between layers, and the size and/or shape of multiple copper through-hole posts may be the same or different; the copper through-hole post can be either a solid copper post or a hollow post electroplated with copper.

It is noted that some embodiments of the present application have been described above. Other embodiments are within the scope of the following claims.

Referring to FIGS. 3A-3L, cross-sectional schematic views of intermediate structures of various steps of a method for manufacturing the device package substrate structure of FIG. 1 are shown.

The manufacturing method includes the steps of: providing a first temporary bearing plate 600-step (a), as shown in FIG. 3A. The material of the first temporary bearing plate 600 is not limited and may be selected according to specific requirements. For example, metallic aluminum, copper, stainless steel, or FR4 resin materials may be selected.

Next, the component 300 is fitted to the first temporary bearing plate 600-step (b), as shown in FIG. 3B. In general, the component 300 may be fitted after the adhesive film 610 is formed on the surface of the first temporary bearing plate 600.

In general, fitting the component 300 on the first temporary bearing plate 600 may specifically include the following sub-steps:
(b₁) forming an adhesive film 610 on the first temporary bearing plate 600. The adhesive film 610 may be formed on one side of the first temporary support plate 600, typically by coating or laminating. The material of the adhesive film 610 may be a double-sided adhesive tape or an adhesive resin film.
(b₂) The component 300 is fitted to the adhesive film 610 at a predetermined position, and the terminal face of the component 300 is fitted to the adhesive film 610 to fix the component 300 against displacement. In general, the component 300 can be fitted to a designated position of the first temporary bearing plate 600 by aligning such that the component can be temporarily fixed on the surface of the first temporary bearing plate 600 by the adhesive film 610.

Then, the first dielectric layer 400 and the second temporary bearing plate 700 are laminated on the surface of the component 300-step (c), as shown in FIG. 3C. In general, this step may include the following sub-steps:
(c₁) laminating the first dielectric layer 400 on the surface of the component 300. In general, an insulation layer is superposed on the surface of the first temporary bearing plate 600 which is fitted to the component 300, and is pressed to form the first dielectric layer 400 to package and protect the component. The first dielectric layer 400 may be selected from a resin film or a liquid packaging material, such as RCC, RCF, or ABF, etc. In some embodiments, the thickness of first dielectric layer 400 exceeds the thickness of component 300 such that component 300 is embedded within the first dielectric layer 400.
(c₂) A second temporary bearing plate 700 is laminated on the surface of the first dielectric layer 400; the second temporary bearing plate 700 includes a support plate 710 and a second copper layer 720 and a first copper layer 730 sequentially laminated on the support plate 710. Typically, a first copper layer 730 is fitted to the first dielectric layer 400. The second temporary bearing plate 700 may be used to support the packaged component 300 after separating the first temporary bearing plate 600. The material of the second temporary support plate 700 can be selected from metal aluminum, copper, stainless steel or FR4 resin. The first copper layer 730 and the second copper layer 720 may be combined in a physical bonding such that the first copper layer 730 and the second copper layer 720 may be easily separated to remove the second temporary bearing plate 700.

Next, the first temporary bearing plate 600 is removed, exposing the terminal face of the component 300 and the first surface of the first dielectric layer 400-step (d), as shown in FIG. 3D. The first temporary bearing plate 600 and the adhesive film 610 can be generally removed by dividing the plates.

Then, a connection pad 310 connecting terminals of the component 300 is formed on the first surface, and the connection pad 310 has an annular ring structure 311-step (e), as shown in FIG. 3E. In general, the process of forming the connection pad 310 can be a seed layer manufacturing-line pattern manufacturing-line pattern electroplating-stripping-etching, which includes the following sub-steps:
(e₁) forming a metal seed layer on the first surface. In general, the metal seed layer may be formed by a sputtering process. The material of the metal seed layer is not particularly limited and can be determined according to actual requirements, and generally can be titanium or copper or titanium copper.
(e₂) A window pattern for manufacturing the connection pad 310 is formed on the surface of the metal seed layer. The window pattern can generally be made by applying a photoresist layer to the surface of the metal seed layer.
(e₃) The connection pad 310 is electroplated in the window pattern, as shown at A. The connection pad 310 has an annular ring structure 311 having an opening 312, an enlarged cross-sectional view of which is as shown in FIG. 3F. The opening 312 can be provided at the center of the annular ring structure 311, i.e., the center of the connection pad 310 has the opening 312, so that it can be satisfied that the connection pad 310 (i.e., the pin fan-out line) of the flip chip I/O connection terminal is connected to the subsequent line layer (i.e., the line layer of the substrate) of the circuit board 100. The opening 312 of the connection pad 310 may be designed according to the size requirements of the laser aperture.
(e₄) Performing a stripping treatment on the photoresist layer to remove the photoresist layer.
(e₅) Performing etching treatment.

Next, a circuit board 100 is manufactured-step (f), as shown in FIG. 3G. Alternatively, the circuit board 100 is formed before any of the above steps (a) to (e). The circuit board 100 includes at least one circuit layer on at least a surface thereof. It will be appreciated that the circuit layer is provided on at least one side surface of the circuit board 100 adjacent to the component 300 to form a conductive interconnection with the component 300. The specific number of circuit layers can be set according to practical application requirements. For example, the circuit layers may include a first circuit layer 110 and a second circuit layer 120 provided on a side of the circuit board 100 remote from the component 300 (i.e. a lower surface of the circuit board 100) and a side of the circuit board 100 near the component 300 (i.e. an upper surface of the circuit board 100), respectively. In some embodiments, the circuit layer may also include a third circuit layer 130 provided between the first circuit layer 110 and the second circuit layer 120, as shown in FIG. 3G. Accordingly, the circuit board 100 may be provided in 1.5 layers, two or more layers. It will be appreciated that corresponding interlayer conductive columns 140 may be provided between two adjacent circuit layers. The number of the interlayer conductive columns 140 may be set as one or more, which is determined according to requirements.

Then, the second dielectric layer 200 and the circuit board 100 are laminated on the first surface; the circuit board 100 includes at least one circuit layer; the second temporary bearing plate 700 is removed to expose a second surface of the first dielectric layer 400 away from the terminal face-step (g), as shown in FIG. 3H. The packaged component 300 may typically be flipped onto the circuit board 100. The material of the second dielectric layer 200 can be selected from a resin film, a liquid packaging material, etc. such as RCC, RCF or ABF, etc.

In some embodiments, the second temporary bearing plate 700 may be completely removed by simply tearing the first and second copper layers 730 and 720 apart and then etching away the first copper layer 730, taking advantage of the physical bonding properties of the first and second copper layers 730 and 720.

Next, a stepped hole 530 is formed, including a first via hole 410 penetrating the first dielectric layer 400, an opening 312 of the annular ring structure 311, and a second via hole 210 penetrating the second dielectric layer 200-step (h), as shown in FIG. 3I. It is understood that the first via hole 410, the second via hole 210, and the opening 312 may be coaxially provided in a direction perpendicular to the circuit board 100, wherein the first via hole 410 and the second via hole 210 are stepped. In general, this step may include the following sub-steps:
(h₁) laser treating the first dielectric layer 400, as shown in FIG. 3J to form a first via hole 410 penetrating the first dielectric layer 400, as shown in FIG. 3K. The diameter of the first via hole 410 may be larger than the aperture of the annular ring structure 311. The number of first via holes 410 may correspond to the number of connection pads 310 of the component 300.
(h₂) Laser treating the second dielectric layer 200 to form a second via hole 210 penetrating the second dielectric layer 200, as shown in FIG. 3L. The positions of the first via hole 410 and the second via hole 210 corresponding to the same annular ring structure 311 are corresponding. Thus, the first via hole 410, the opening 312 of the annular ring structure 311, and the second via hole 210 form a stepped hole 530 in the vertical direction, forming a communication channel between the component 300 and the circuit board 100, as shown in FIG. 3I.

Then, a conductive column 500b for conductively connecting the connection pad 310 of the component 300 with the circuit layer on the surface of the circuit board 100 is formed by filling the stepped hole 530, and the conductive column 500b passes through at least the opening 312 and the second via hole 210 to make the connection pad 310 conductive with the circuit layer-step (i), as shown in FIG. 1 or FIG. 2. The number of the conductive columns 500b corresponds to the number of the annular ring structures 311. In general, this step may include the following sub-steps:
(i₁) performing an electroplating process on the first via hole 410 and the second via hole 210 to form a conductive column penetrating the first via hole 410 and the second via hole 210, resulting in the structure as shown in FIG. 1. Here, on the first dielectric layer 400, the conductive column 500b has a window pad 510.

In some embodiments, a substep (i₂) of removing the window pad 510 and forming a conductive column 500b through only the second via hole 210 and the opening 312 may also be included, resulting in the structure as shown in FIG. 2. In general, blind drilling may be performed by deep drilling with mechanical holes to remove localized metal of the stepped hole 530, such as removing the window pad 510 in the first via hole 410 or removing a portion of the window pad 510 in the first via hole 410, thereby forming only inner layer line conduction.

The component package substrate structure and the manufacturing method thereof provided in the embodiments of the present application are as follows: the component 300 is embedded after the circuit board 100 (i.e., a substrate) is completed, and after the embedding process of the component 300 is performed, the component 300 and the substrate circuit are conducted through the stepped hole 530 to avoid the component being discarded as useless due to the failure of the substrate circuit and improve the packaging yield of the component 300. The stepped hole 530 can realize the conduction between the component 300 and the inner layer line and the back side fan-out of the component 300, and has a high degree of freedom in wiring, so that a multi-device package can be achieved and the package integration degree can be improved. The length of the signal circuit can be reduced and the loss of signal transmission process can be reduced by the conductive interconnection via the conductive columns in the stepped hole.

In some cases, the acts or steps recited in the claims may be performed in an order other than that of the embodiments described above and still achieve the desired results. Additionally, the processes depicted in the figures do not necessarily require the particular order or sequential order shown to achieve desired results. Multi-tasking and parallel processing are also possible or may be advantageous in some embodiments.

A person skilled in the art will appreciate that the discussion of any embodiment above is merely exemplary and is not intended to imply that the scope of the present application, including the claims, is limited to these examples; combinations of features in the above embodiments, or between different embodiments, may also be made within the spirit of the present application, the steps may be implemented in any order, and there may be many other variations of the different aspects of the embodiments of the present application as described above, which are not provided in detail for clarity.

In addition, well-known power/ground connections to integrated circuit (IC) chips and other components may or may not be shown in the provided figures for simplicity of illustration and discussion, and so as not to obscure the embodiments of the present application. Further, devices may be shown in block diagram form in order to avoid obscuring the embodiments of the present application, and this also takes into account the fact that the details regarding the implementation of such block diagram devices are highly dependent upon the platform on which the embodiments of the present application are to be implemented (i.e. such details should be well understood by a person skilled in the art). Where specific details (e.g. circuits) are set forth in order to describe example embodiments of the present application, it will be apparent to a person skilled in the art that the embodiments of the present application may be practiced without, or with variation of, these specific details. Accordingly, the description is to be regarded as illustrative rather than restrictive.

While the present application has been described in conjunction with specific embodiments thereof, it is evident that many alternatives, modifications, and variations will be apparent to a person skilled in the art in light of the foregoing description. For example, other memory architectures (e.g. dynamic RAM (DRAM)) may use the discussed embodiments.

The embodiments of the present application are intended to embrace all such alternatives, modifications and variances which fall within the broad scope of the appended claims. Therefore, any omissions, modifications, substitutions, improvements and the like that may be made without departing from the spirit or scope of the embodiments of the present application are intended to be included within the scope of the present application.

What is claimed is:

1. A method for manufacturing a component package substrate structure, the method comprising:
providing a first temporary bearing plate;
fitting a component on the first temporary bearing plate;
applying a first dielectric layer on the first temporary bearing plate such that the component is embedded in the first dielectric layer;
applying a second temporary bearing plate on the first dielectric layer;
removing the first temporary bearing plate to expose a terminal face of the component and a first surface of the first dielectric layer;
forming a connection pad connected to a terminal of the component on the first surface, the connection pad comprising an annular ring structure;
laminating a second dielectric layer on the first surface, and laminating a circuit board on the second dielectric layer, wherein the surface of the circuit board fitted to the second dielectric layer comprises a circuit layer;
removing the second temporary bearing plate to expose a second surface of the first dielectric layer;
opening a stepped hole on the second surface, wherein the stepped hole comprises a first via hole penetrating the first dielectric layer, an opening of an annular ring structure of the connection pad and a second via hole penetrating the second dielectric layer, wherein the first via hole, the opening and the second via hole together expose the circuit layer; and
electroplating the stepped hole to form a conductive column, wherein the conductive column renders the connection pad conductive with the circuit layer.

2. The method according to claim 1, further comprising:
forming a pad connected to the conductive column on the first dielectric layer.

3. The method according to claim 2, further comprising:
removing a portion of the conductive column within the first via hole.

4. The method according to claim 1, wherein the forming of the connection pad connected to the terminal comprises:
forming a metal seed layer on the first surface;
forming a window pattern for manufacturing a connection pad on the metal seed layer; and
electroplating to form the connection pad within the window pattern.

5. The method according to claim 1, wherein the circuit board is a multi-layer substrate having at least one circuit layer.

6. The method according to claim 1, wherein the fitting of the component on the first temporary bearing plate comprises:
forming an adhesive film on the first temporary bearing plate; and
fitting the component at a predetermined position on the adhesive film such that a terminal face of the component is fitted to the adhesive film.

7. The method according to claim 1, wherein the second temporary bearing plate comprises a support plate, a second metal layer on the support plate, and a first metal layer physically laminated on the second metal layer, wherein the first metal layer is laminated on the first dielectric layer.

8. The method according to claim 7, wherein the first metal layer and the second metal layer comprise a copper layer.

9. The method according to claim 7, wherein the support plate is selected from the group consisting of a resin, aluminum, stainless steel, and copper.

10. A component package substrate structure comprising:
a circuit board having a surface having a circuit layer; a second dielectric layer provided on the circuit layer of the circuit board, the second dielectric layer having a second via hole penetrating the second dielectric layer and exposing the circuit layer;
a component having a terminal face facing the second dielectric layer, a connection pad connected to a terminal of the component being provided on the terminal face, the connection pad comprising an annular ring structure having an opening, wherein the opening exposes the second via hole;
a first dielectric layer provided on the second dielectric layer and embedding the component, the first dielectric layer having a first via hole penetrating the first dielectric layer and exposing the opening; and
a conductive column filling at least the second via hole and the opening of the connection pad to make the connection pad be conductive with the circuit layer.

11. The component package substrate structure according to claim 10, further comprising a pad on the first dielectric layer to connect the conductive column.

12. The component package substrate structure according to claim 10, wherein the circuit board comprises a multilayer substrate having at least one circuit layer.

13. The component package substrate structure according to claim 10, wherein the first via hole, the opening of the connection pad, and the second via hole are coaxially provided.
